(19) United States
(12) Patent Application Publication
(10) Pub. No.: US 2025/0387870 A1
(43) Pub. Date: Dec. 25, 2025

(54) PROCESSING APPARATUS

(71) Applicant: Ebara Corporation, Tokyo (JP)

(72) Inventors: Yuichi SATO, Tokyo (JP); Kohei OTA, Tokyo (JP); Nobuyuki TAKADA, Tokyo (JP)

(73) Assignee: Ebara Corporation, Tokyo (JP)

(21) Appl. No.: 19/247,774

(22) Filed: Jun. 24, 2025

(30) Foreign Application Priority Data
Jun. 25, 2024 (JP) 2024-101770

(51) Int. Cl. B24B 37/10

(52) U.S. Cl. CPC B24B 37/107

(57) ABSTRACT

Provided is a technique for processing a substrate in a short time. A processing apparatus 1 includes a table 10 configured to hold a substrate Wf such that a surface to be processed of the substrate faces upward, a table rotation device 20 configured to rotate the table, a plurality of heads 30a, 40a to each of which a processing pad Pd1, Pd2 is attached, the processing pad having an area smaller than an area of the surface to be processed of the substrate, a plurality of head rotation devices 50a, 55a, a plurality of pressing devices 60a, 65a, each of the plurality of pressing devices has an electromagnetic actuator configured to apply a pressing force to a corresponding one of the plurality of heads by utilizing electromagnetic force, and a plurality of swing devices 70a, 80a.

### CROSS-REFERENCE TO A RELATED APPLICATION

This application claims the benefit of Japanese Patent Application No. 2024-101770, filed Jun. 25, 2024.

### TECHNICAL FIELD

The present invention relates to a processing apparatus. This application claims priority from Japanese Patent Application No. 2024-101770 filed on Jun. 25, 2024. The entire disclosure including the descriptions, the claims, the drawings, and the abstracts in Japanese Patent Application No. 2024-101770 is herein incorporated by reference.

### BACKGROUND ART

There have been conventionally known processing apparatuses configured to perform a predetermined process (for example, polishing process) on a substrate. Specifically, there have been known processing apparatuses that include a table configured to hold a substrate such that the substrate surface to be processed faces upward, and a head configured to hold a single processing pad and bring the processing pad into contact with the substrate surface to be processed (for example, refer to PTL 1 and PTL 2). In the processing apparatuses exemplified in PTL 1 and PTL 2, an area of the processing pad is smaller than an area of the substrate surface to be processed. With this configuration, the substrate surface to be processed can be locally processed by the processing pad.

### CITATION LIST

### Patent Literature

PTL 1: Japanese Unexamined Patent Application Publication No. 2016-58724
PTL 2: Japanese Unexamined Patent Application Publication No. 2017-64801

### SUMMARY OF INVENTION

### Technical Problem

However, the above-described conventional processing apparatuses have room for improvement in terms of processing substrates in a short period of time.

The present invention has been made in view of the above-described circumstance, and it is an object of the present invention to provide a technique allowing processing a substrate in a short period of time.

### Solution to Problem

### (Aspect 1)

In order to achieve the above-described object, a processing apparatus according to one aspect of the present invention is a processing apparatus configured to perform a polishing process on a substrate as a predetermined process, and includes: a table configured to hold the substrate such that a surface to be processed of the substrate faces upward; a table rotation device configured to rotate the table; a plurality of heads to each of which a processing pad is attached, the processing pad having an area smaller than an area of the surface to be processed of the substrate, the plurality of heads being configured to bring the processing pad into contact with the surface to be processed of the substrate; a plurality of head rotation devices each configured to rotate a corresponding one of the plurality of heads; a plurality of pressing devices each including an electromagnetic actuator configured to apply a pressing force to a corresponding one of the plurality of heads by utilizing electromagnetic force; and a plurality of swing devices each configured to swing a corresponding one of the plurality of heads.

According to this aspect, since the plurality of processing pads can be used to process the substrate, the substrate can be processed in a shorter time than when only a single processing pad is used to process the substrate.

Further, according to this aspect, since the pressing devices include electromagnetic actuators, a pressing force can be applied to the heads more quickly compared to a case in which the pressing devices include pressing mechanisms such as air cylinders instead of electromagnetic actuators. In this respect as well, according to this aspect, the substrate can be processed in a short time.

### (Aspect 2)

In the above-described aspect 1, each of the plurality of heads may include a holder plate to which the processing pad is attached, a base plate arranged above the holder plate, and a rubber buffer plate arranged between the holder plate and the base plate.

### (Aspect 3)

In the above-described aspect 1 or 2, an outer edge region is a region extending a predetermined distance from an outer edge of a top surface of the table toward a center of the top surface, and the outer edge region may be provided with a plurality of discharge ports configured to discharge liquid toward a bottom surface of the substrate placed on the top surface.

### (Aspect 4)

In any one of the above-described aspects 1 to 3, the plurality of heads may include a first head to which a first processing pad is attached and a second head to which a second processing pad is attached, the plurality of swing devices may include a first swing device configured to swing the first head and a second swing device configured to swing the second head, the first swing device may include a first swing shaft and is configured to swing the first head around the first swing shaft, the second swing device may include a second swing shaft and is configured to swing the second head around the second swing shaft, and the first swing shaft and the second swing shaft may be arranged in a region outer than the table in a top view.

### (Aspect 5)

In the above-described aspect 4, assuming a first center axis line that passes through a center of the table in the top view and a second center axis line that passes through the center and is perpendicular to the first center axis line, the first swing shaft and the second swing shaft may be arranged in one of two regions defined by the first center axis line, the first swing shaft may be arranged in one of two regions defined by the second center axis line, and the second swing shaft may be arranged in the other of the two regions defined by the second center axis line.

### BRIEF DESCRIPTION OF DRAWINGS

FIG. 1 is a schematic diagram illustrating main configurations of a processing apparatus according to an embodiment;

FIG. 2 is a schematic top view for describing the swing of a plurality of heads according to the embodiment;

FIG. 3 is a schematic top view describing a state in which the plurality of heads according to the embodiment are not positioned above a table.

FIG. 4A is a schematic diagram for describing a peripheral configuration of a first head according to the embodiment; FIG. 4B is a schematic diagram for describing a peripheral configuration of a second head according to the embodiment;

FIG. 5A is a schematic top view of a buffer plate according to the embodiment; FIG. 5B is a schematic bottom view of the buffer plate according to the embodiment;

FIG. 6A is a schematic top view of the table according to the embodiment; FIG. 6B is a schematic cross-sectional view of the table according to the embodiment;

FIG. 7 is a schematic cross-sectional view for describing details of a first pressing device according to the embodiment;

FIG. 8 is a schematic cross-sectional view for describing details of the first pressing device according to the embodiment;

FIG. 9 is a schematic diagram for describing a processing apparatus according to Modification 1 of the embodiment;

FIG. 10 is a schematic diagram for describing a processing apparatus according to Modification 2 of the embodiment;

FIG. 11 is a schematic diagram for describing a dresser according to the embodiment; and

FIG. 12 is a schematic diagram for describing an example of control according to the embodiment.

### DESCRIPTION OF EMBODIMENTS

### Embodiment

The following describes embodiments of the present invention with reference to the drawings. Note that the drawings are schematically illustrated to facilitate understanding of features, and dimensional proportions and the like of each constituent element are not necessarily the same as the actual ones. In the drawings, orthogonal coordinates of X-Y-Z are illustrated as necessary. Of the orthogonal coordinates, the Z-direction corresponds to an upper side, and the −Z-direction corresponds to a lower side (direction in which gravity acts).

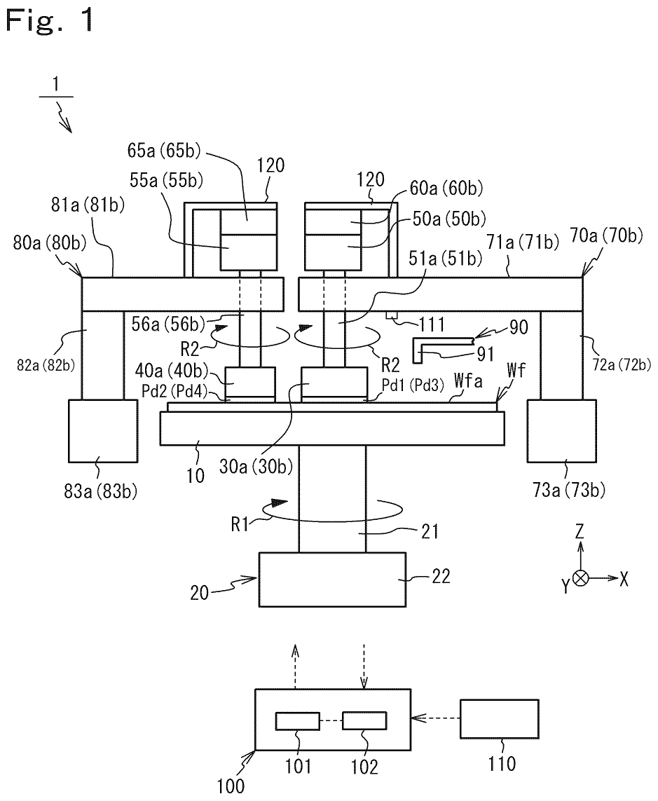

FIG. 1 is a schematic diagram illustrating main configurations of a processing apparatus 1 according to the present embodiment. The processing apparatus 1 according to the present embodiment is a processing apparatus configured to perform a predetermined process on a substrate Wf. The predetermined process is not particularly limited as long as the substrate Wf can be processed using a processing pad, and may be any known process such as a polishing process or a cleaning process. In the present embodiment, a polishing process is taken as an example of the predetermined process. A specific example of the polishing process is not particularly limited, and may be chemical mechanical polishing (CMP), mechanical polishing other than chemical mechanical polishing, and the like. In the present embodiment, chemical mechanical polishing is taken as an example of polishing.

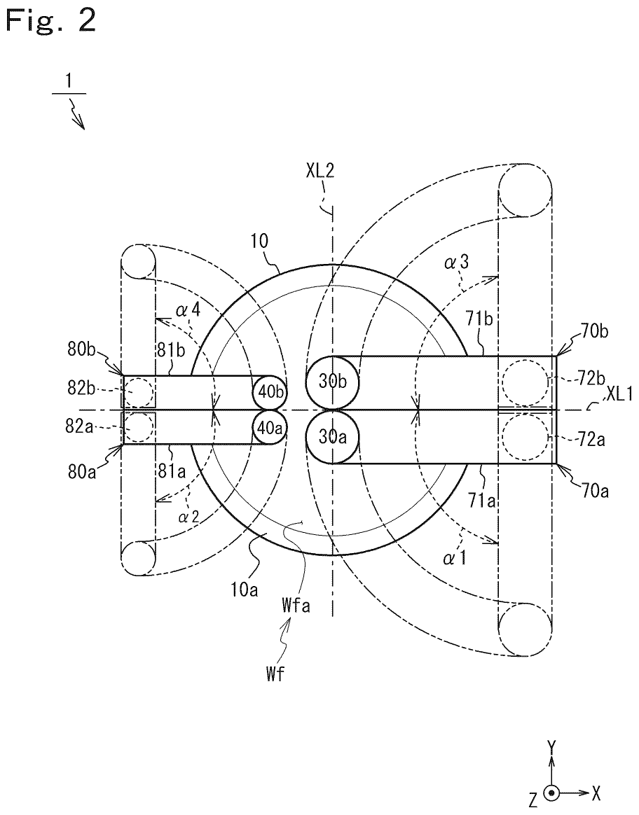

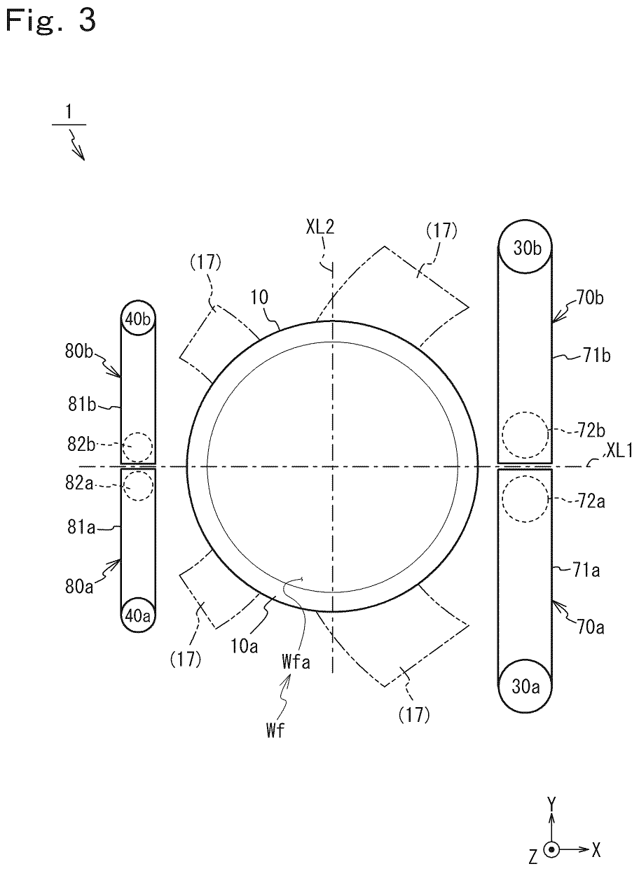

The processing apparatus 1 illustrated in FIG. 1 includes a table 10, a table rotation device 20, a plurality of heads, a plurality of head rotation devices, a plurality of pressing devices, a plurality of swing devices, a process liquid supply device 90, a control device 100, and a sensor group 110. FIG. 2 is a schematic top view for describing the swing of the plurality of heads. FIG. 2 does not illustrate the head rotation devices, the pressing devices, and the like. FIG. 3 is a schematic top view describing a state in which the plurality of heads are not positioned above the table 10.

Referring to FIGS. 1, 2, and 3, the plurality of heads according to the present embodiment include, as an example, four heads (first head 30a, second head 40a, third head 30b, and fourth head 40b). The plurality of head rotation devices according to the present embodiment include, as an example, four head rotation devices (first head rotation device 50a, second head rotation device 55a, third head rotation device 50b, and fourth head rotation device 55b). The plurality of pressing devices according to the present embodiment include, as an example, four pressing devices (first pressing device 60a, second pressing device 65a, third pressing device 60b, and fourth pressing device 65b). The plurality of swing devices according to the present embodiment include, as an example, four swing devices (first swing device 70a, second swing device 80a, third swing device 70b, and fourth swing device 80b).

Referring to FIG. 1, the table 10 is configured to hold the substrate Wf. Specifically, the table 10 according to the present embodiment holds the substrate Wf on the top surface of the table 10 such that a surface to be processed Wfa of the substrate Wf faces upward at least when the substrate Wf is subjected to a predetermined process (hereinafter referred to as “at the time of substrate processing” or simply “at the time of processing”). As an example, an area of the substrate Wf is illustrated in FIG. 2 as being smaller than an area of the table 10, but this is not limiting. The area of the substrate Wf may be the same as the area of the table 10 (that is, the substrate Wf may have the same diameter as the table 10).

The specific method for holding the substrate Wf by the table 10 is not particularly limited. As an example, the table 10 according to the present embodiment holds the substrate Wf by a vacuum chuck method (details of the vacuum chuck method will be described later).

The specific shape of the substrate Wf is not particularly limited, and may be circular, angular (square or the like), or another shape. The substrate Wf according to the present embodiment has a circular shape, as an example.

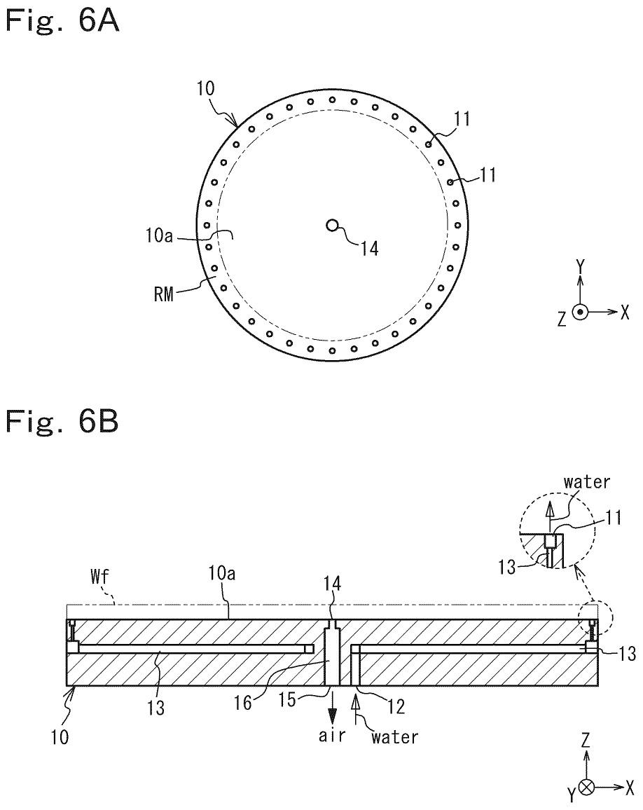

At the time of placing the substrate Wf on the table 10, water may be supplied from a water supply mechanism onto the top surface of the table 10 to form a liquid film on the top surface of the table 10, and then the substrate Wf may be arranged on the top surface of the table 10 on which the liquid film has been formed, and then the substrate Wf may be held on the table 10 by the vacuum chuck method. In this case, as the water supply mechanism, discharge ports 11 (FIG. 6B) described later may be used, or water supply nozzles (not illustrated) capable of supplying water to the top surface of the table 10 and the like may be used. In this way, arranging the substrate Wf on the top surface of the table 10 on which the liquid film has been formed makes it possible to effectively prevent the occurrence of scratches and the like on the substrate Wf.

In addition, At the time of placing the substrate Wf on the table 10, a process for aligning the center of the substrate Wf with the center of the table 10 (referred to as “centering process of the substrate Wf”) may be performed. In this case, the centering process of the substrate Wf may be performed using a predetermined centering device (such as the device described in Japanese Unexamined Patent Application Publication No. 2021-122902), for example. Specifically, a plurality of centering devices are arranged to surround the periphery of the substrate Wf, and are configured to press the outer peripheral edge of the substrate Wf arranged on the table 10 toward the center of the table 10 to align the center of the substrate Wf with the center of the table 10. In the case of performing the centering process of the substrate Wf, after performing the centering process, the substrate Wf may be held on the table 10 by the vacuum chuck method, for example. The centering process may be performed in a state where a liquid film exists between the substrate Wf and the table 10.

The table rotation device 20 is configured to rotate the table 10 during processing. Specifically, the table rotation device 20 according to the present embodiment includes, as an example, a table rotation shaft 21 connected to the table 10, and a table driving device 22 configured to rotate the table rotation shaft 21. The table driving device 22 includes a known driving device such as a motor, for example. In FIG. 1, an example of the direction of rotation of the table rotation shaft 21 is indicated as “R1.”

Referring to FIGS. 1 and 2, the first head 30a is configured such that a first processing pad Pd1 is attached thereto. The first head 30a is also configured to bring the first processing pad Pd1 into contact with the surface to be processed Wfa of the substrate Wf. The second head 40a is configured such that a second processing pad Pd2 is attached thereto. The second head 40a is configured to bring the second processing pad Pd2 into contact with the surface to be processed Wfa of the substrate Wf.

The third head 30b is configured such that a third processing pad Pd3 is attached thereto. The third head 30b is configured to bring the third processing pad Pd3 into contact with the surface to be processed Wfa of the substrate Wf. The fourth head 40b is configured such that a fourth processing pad Pd4 is attached thereto. The fourth head 40b is configured to bring the fourth processing pad Pd4 into contact with the surface to be processed Wfa of the substrate Wf.

The plurality of processing pads (Pd1, Pd2, Pd3, and Pd4) according to the present embodiment are members for processing the surface to be processed Wfa of the substrate Wf (for example, polishing process) by sliding against the surface to be processed Wfa. The specific type of these processing pads is not particularly limited, and any processing pads used for known substrate processing can be used.

In the present embodiment, an area of each of the plurality of processing pads (Pd1, Pd2, Pd3, and Pd4) is smaller than an area of the surface to be processed Wfa of the substrate Wf (in the present embodiment, the top surface of the substrate Wf). This configuration makes it easier to locally polish the surface to be processed Wfa of the substrate Wf by the processing pads, compared to the case where the area of the processing pads is equal to or larger than the area of the surface to be processed Wfa of the substrate Wf.

As an example, an area of the first processing pad Pd1 according to the present embodiment is larger than an area of the second processing pad Pd2. In other words, the area of the second processing pad Pd2 is smaller than the area of the first processing pad Pd1. Similarly, an area of the third processing pad Pd3 is larger than an area of the fourth processing pad Pd4. Also, the area of the third processing pad Pd3 is larger than the area of the second processing pad Pd2.

The area ratio between the first processing pad Pd1 and the third processing pad Pd3 is not particularly limited, but in the present embodiment, as an example, the area of the first processing pad Pd1 is the same as the area of the third processing pad Pd3. The area ratio between the second processing pad Pd2 and the fourth processing pad Pd4 is not particularly limited, but in the present embodiment, as an example, the area of the second processing pad Pd2 is the same as the area of the fourth processing pad Pd4. However, the present invention is not limited to this, and the area of the first processing pad Pd1 may be larger or smaller than the area of the third processing pad Pd3. Similarly, the area of the second processing pad Pd2 may be larger or smaller than the area of the fourth processing pad Pd4.

As an example of numerical values of the area ratio, the areas of the first processing pad Pd1 and the third processing pad Pd3 may each be 10% or less (as an example, 5% or more and 10% or less) of the area of the surface to be processed Wfa of the substrate Wf. In addition, the area of the second processing pad Pd2 (or the fourth processing pad Pd4) may be 70% or less (as an example, 20% or more and 70% or less) of the area of the first processing pad Pd1 (or the third processing pad Pd3). However, these area ratios are merely examples, and the specific area ratios may be set as appropriate depending on the type of the substrate Wf or the like.

As described above, in the present embodiment, the area of the first processing pad Pd1 is larger than the area of the second processing pad Pd2, and the area of the third processing pad Pd3 is larger than the area of the fourth processing pad Pd4, but the present invention is not limited to this configuration. The areas of the plurality of pads (Pd1, Pd2, Pd3, and Pd4) of the processing apparatus 1 may be the same value.

As described above, the processing apparatus 1 according to the present embodiment includes four heads as an example, but the present invention is not limited to this configuration. The processing apparatus 1 needs to include at least two heads (for example, the first head 30a and the second head 40a). That is, the processing apparatus 1 may not include any heads other than the first head 30a and the second head 40a, or may include only one head or three or more heads other than the first head 30a and the second head 40a.

The plurality of head rotation devices (50a, 55a, 50b, and 55b) are configured to rotate the plurality of heads (30a, 40a, 30b, and 40b) during processing.

Specifically, the first head rotation device 50a according to the present embodiment is connected to the first head 30a via a head rotation shaft 51a, as an example, and rotates the first head 30a by rotating the head rotation shaft 51a. The second head rotation device 55a according to the present embodiment is connected to the second head 40a via a head rotation shaft 56a, as an example, and rotates the second head 40a by rotating the head rotation shaft 56a. The third head rotation device 50b according to the present embodiment is connected to the third head 30b via a head rotation shaft 51b, as an example, and rotates the third head 30b by rotating the head rotation shaft 51b. The fourth head rotation device 55b according to the present embodiment is connected to the fourth head 40b via a head rotation shaft 56b, as an example, and rotates the fourth head 40b by rotating the head rotation shaft 56b.

In FIG. 1, an example of the direction of rotation of the plurality of heads is indicated as “R2.” In the present embodiment, the rotation direction of the plurality of heads is the same as the rotation direction of the table 10, as an example.

Each of the plurality of head rotation devices (50a, 55a, 50b, and 55b) includes a known driving device such as a motor. The configuration of such a head rotation device is similar to those of the known head rotation devices disclosed in PTL 1 and PTL 2, and thus further detailed description thereof will be omitted.

The first pressing device 60a is configured to apply a pressing force to the first head 30a during processing. The second pressing device 65a is configured to apply a pressing force to the second head 40a during processing. The third pressing device 60b is configured to apply a pressing force to the third head 30b during processing. The fourth pressing device 65b is configured to apply a pressing force to the fourth head 40b during processing. These pressing devices are connected to arms (arms 71a, 81a, 71b, and 81b) corresponding thereto via a connecting member 120. The details of the pressing devices will be described later.

The plurality of swing devices (70a, 80a, 70b, and 80b) are configured to swing the plurality of heads (30a, 40a, 30b, and 40b) during processing.

Specifically, the first swing device 70a according to the present embodiment includes, as an example, an arm 71a that extends horizontally and is connected to the first head 30a via the head rotation shaft 51a, a swing shaft 72a (first swing shaft) that is connected to an end of the arm 71a and extends vertically, and a driving device 73a that is configured to drive the swing shaft 72a to swing. The first swing device 70a swings the first head 30a parallel to the top surface of the table 10 (that is, parallel to the surface to be processed Wfa of the substrate Wf) by swinging the arm 71a in a horizontal plane about the swing shaft 72a.

The second swing device 80a according to the present embodiment includes, as an example, an arm 81a that extends horizontally and is connected to the second head 40a via the head rotation shaft 56a, a swing shaft 82a (second swing shaft) that is connected to an end of the arm 81a and extends vertically, and a driving device 83a that is configured to drive the swing shaft 82a to swing. The second swing device 80a swings the second head 40a parallel to the top surface of the table 10 by swinging the arm 81a in a horizontal plane around the swing shaft 82a.

The third swing device 70b according to the present embodiment includes, as an example, an arm 71b that extends horizontally and is connected to the third head 30b via the head rotation shaft 51b, a swing shaft 72b (third swing shaft) that is connected to an end of the arm 71b and extends vertically, and a driving device 73b that is configured to drive the swing shaft 72b to swing. The third swing device 70b swings the third head 30b parallel to the top surface of the table 10 by swinging the arm 71b in a horizontal plane around the swing shaft 72b.

The fourth swing device 80b according to the present embodiment includes, as an example, an arm 81b that extends horizontally and is connected to the fourth head 40b via the head rotation shaft 56b, a swing shaft 82b (fourth swing shaft) that is connected to an end of the arm 81b and extends vertically, and a driving device 83b configured to drive the swing shaft 82b to swing. The fourth swing device 80b swings the fourth head 40b parallel to the top surface of the table 10 by swinging the arm 81b in a horizontal plane around the swing shaft 82b.

The configurations of these swing devices are similar to those of known swing devices as disclosed in PTL 1 and PTL 2, and thus further detailed description thereof will be omitted.

In addition, the specific dimensions of the plurality of arms and the like are not particularly limited. However, the length of arms may be set such that at least one pad selected from the plurality of pads can process the entire surface to be processed Wfa of the substrate Wf (that is, the entire surface to be processed Wfa from the center to the outer edge), for example. As a specific example, the length of the arm 71a may be set such that at least the first processing pad Pd1 can process (polish) the entire surface to be processed Wfa of the substrate Wf.

Referring to FIG. 1, the processing liquid supply device 90 is a device for supplying a processing liquid (in the present embodiment, a polishing slurry as an example) onto the substrate Wf during processing. The processing apparatus 1 according to the present embodiment polishes the surface to be processed Wfa of the substrate Wf while rubbing the surface to be processed Wfa of the substrate Wf with the processing pads (Pd1, Pd2, Pd3, and Pd4) in the presence of the polishing slurry. The polishing slurry is composed of a liquid containing a processing agent such as abrasive grains. The processing liquid supply device 90 according to the present embodiment is configured to supply the polishing slurry to the surface to be processed of the substrate Wf from a processing liquid supply nozzle 91 as an example.

The processing liquid supply nozzle 91 may be configured to swing together with the head. Specifically, in this case, the processing liquid supply nozzle 91 may be connected to at least one arm selected from the plurality of arms (arms 71a, 71b, 81a, and 81b) and may supply the polishing slurry while swinging together with the connected arm. Also in this case, the processing liquid supply device 90 may include a plurality of processing liquid supply nozzles 91. The processing liquid supply nozzle 91 may be arranged so as to supply the polishing slurry onto the substrate Wf positioned upstream of at least one head selected from the plurality of heads in the rotation direction of the substrate Wf.

If the processing apparatus 1 is a cleaning apparatus that performs a cleaning process on the substrate Wf, for example, the process liquid supply device 90 is configured to supply a cleaning liquid (which is also an example of a processing liquid).

The sensor group 110 includes sensors for detecting various physical parameters of the processing apparatus 1. The parameters detected by the sensor group 110 are transmitted to the control device 100.

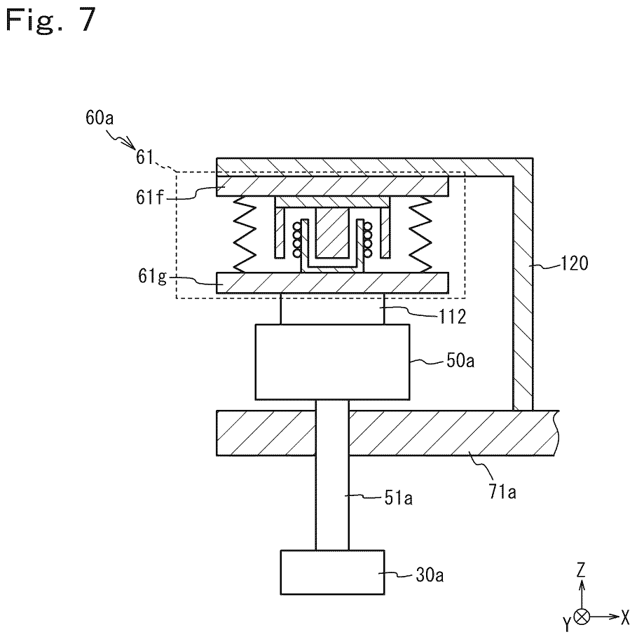

The sensor group 110 according to the present embodiment includes, as an example, a pressure sensor for detecting the pressing force applied by each pressing device. As an example of the pressure sensor, the present embodiment includes a load cell 112 (this reference sign is illustrated in FIG. 7, which will be described later).

The sensor group 110 also includes an swing speed sensor for detecting the swing speed (rotation speed during swing) of each head, a rotation speed sensor for detecting the rotation speed (autorotation speed) of each head, a rotation speed sensor for detecting the rotation speed of the table 10, and the like.

The sensor group 110 also includes a phase sensor for detecting the swing phase (rotation phase) of each head, a phase sensor for detecting the rotation phase of the table 10, and the like.

The sensor group 110 also includes a film thickness sensor 111 for detecting a film thickness on the substrate Wf before and/or during substrate processing. The film thickness sensor 111 according to the present embodiment is arranged on at least one of the plurality of arms (71a, 71b, 81a, and 81b) of the processing apparatus 1, as an example.

The film thickness sensor 111 may detect the film thickness of the substrate Wf at a predetermined representative location. Alternatively, the film thickness sensor 111 may detect the overall film thickness of the substrate Wf (the overall film thickness from the center to the outer edge). In the case of detecting the overall film thickness of the substrate Wf by the film thickness sensor 111, the sensor group 110 may include a plurality of film thickness sensors 111, for example. Alternatively, the film thickness sensor 111 may be arranged on at least one of a plurality of arms (swing arms) of the processing apparatus 1, and measure the overall film thickness of the substrate Wf while swinging together with the arm on which the film thickness sensor 111 is arranged.

Alternatively, if the processing apparatus 1 has three or more arms, one of the arms may not have a head attached thereto but may have a film thickness sensor 111 attached thereto instead. Even in this case, the film thickness sensor 111 can be swung by the arm to easily detect the overall film thickness of the substrate Wf.

The processing apparatus 1 may further include an atomizer device (not illustrated) configured to spray an atomizer liquid (“nitrogen-containing water” as a specific example) toward the top surface of the table 10. Specifically, in this case, the atomizer device may be arranged on at least one of the plurality of arms and may spray the atomizer liquid toward the top surface of the table 10 (or the top surface of the substrate Wf, if the substrate Wf is arranged thereon) while swinging integrally with the arm, for example.

The control device 100 is a device for integrally controlling operations of the processing apparatus 1. Specifically, the control device 100 according to the present embodiment includes a microcomputer. The microcomputer includes a processor 101, a storage device 102 as a non-transitory storage medium, and the like. In the control device 100, the processor 101 controls the operations of the processing apparatus 1 based on instructions of programs stored in the storage device 102, for example.

In addition, during processing, the control device 100 of the present embodiment controls the operations of the table rotation device 20 (specifically, the table driving device 22), each head rotation device, each pressing device, and each swing device (specifically, the driving device for the swing device) based on parameters detected by the sensor group 110 and the like.

The control device 100 may perform all of the substrate processing steps fully automatically based on a program, or may perform all or some of the substrate processing steps based on instructions from a user (operator).

Next, details of the swing shafts and the swing of the plurality of head, and the like will be described with reference to FIGS. 2 and 3. First, the plurality of swing shafts (72a, 82a, 72b, and 82b) according to the present embodiment are arranged in an area outside the table 10 in a top view.

In the top view of the table 10, assume a first center axis line XL1 (extending in the X-axis direction) that passes through the center of the table 10, and a second center axis line XL2 (extending in the Y-axis direction) that passes through the center of the table 10 and is perpendicular to the first center axis line XL1.

The swing shafts 72a and 72b according to the present embodiment are arranged in one of two regions defined by the second center axis line XL2 (the region on the X direction side of the second center axis line XL2). The swing shafts 82a and 82b are arranged in the other of the two regions defined by the second center axis line XL2 (the region on the −X direction side of the second center axis line XL2).

The swing shafts 72a and 82a according to the present embodiment are arranged in one of two regions defined by the first center axis line XL1 (the region on the −Y direction side of the first center axis line XL1), and the swing shafts 72b and 82b are arranged in the other of the two regions defined by the first center axis line XL1 (the region on the Y direction side of the first center axis line XL1).

According to the present embodiment, since the plurality of swing shafts (72a, 82a, 72b, and 82b) are arranged as described above, it is possible to easily restrain the plurality of arms connected to these swing shafts from interfering with each other during swinging. Furthermore, when the substrate Wf is attached to the table 10 or the substrate Wf is removed from the table 10 (that is, “at the attachment/removal of the substrate Wf”), or “during maintenance” such as replacing a processing pad, the heads and the arms can be easily moved as illustrated in FIG. 3 described later. This makes it possible to easily restrain the plurality of swing shafts and the plurality of arms from interfering with these operations.

The swing shafts 72a, 82a, 72b, and 82b according to the present embodiment are arranged in the vicinity of the first center axis line XL1. In the present embodiment, “a member is in the vicinity of the center axis line” specifically means that the value of the distance between the center of the member and the center axis line is smaller than ⅓ of the radius of a top surface 10a of the table 10.

A swing angle range (α1) of the first head 30a, a swing angle range (α2) of the second head 40a, a swing angle range (α3) of the third head 30b, and a swing angle range (α4) of the fourth head 40b according to the present embodiment are each 90°, as an example. However, the swing angle ranges of these heads are not limited to 90°, and may be smaller than 90° or larger than 90°. The swing angle ranges of the plurality of heads may not be the same value but may be different values. In at least one of the first head 30a and the third head 30b, the angle range capable of swinging may be set to be larger than 90° such that the head can polish up to the center of the substrate Wf.

The swing devices (70a, 80a, 70b, and 80b) may swing the heads (30a, 40a, 30b, and 40b) such that the heads move back and forth between a predetermined location on the top surface 10a of the table 10 (in FIG. 2, a location near the first center axis line XL1) and a predetermined location outside the table 10, as illustrated in FIG. 2.

The first swing device 70a and the third swing device 70b may swing the first head 30a and the third head 30b such that the first head 30a and the third head 30b move close to and away from each other. The second swing device 80a and the fourth swing device 80b may swing the second head 40a and the fourth head 40b such that the second head 40a and the fourth head 40b move close to and away from each other.

In the present embodiment, the heads are temporarily positioned outside the table 10 during swinging (that is, the heads protrude outside the table 10), but the present invention is not limited to this configuration. The heads may swing so as to move back and forth between a predetermined location on the top surface 10a of the table 10 and the outer edge of the top surface 10a of the table 10 without protruding outside the table 10.

In the case of a configuration in which the heads protrude outside the table 10 during swinging as in the present embodiment, the processing apparatus 1 may include a support base 17 (as illustrated in FIG. 3) for supporting the heads protruding outside the table 10 from below. When not in use, the support base 17 may be stored inside the processing apparatus 1 and the like (for example, below the table 10). If the processing apparatus 1 includes the support base 17, the outer diameter of the table 10 is preferably the same as the outer diameter of the substrate Wf.

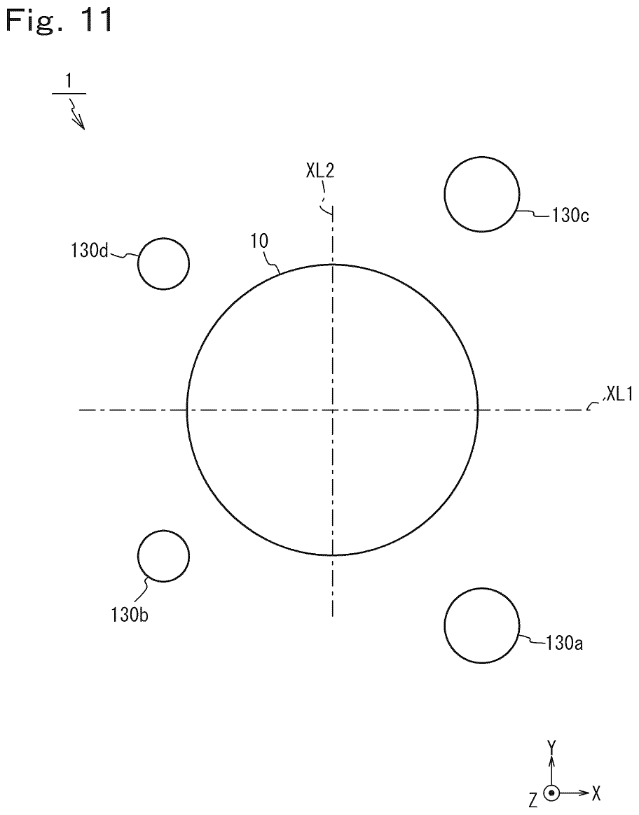

As illustrated in FIG. 11, the processing apparatus 1 may include dressers 130a, 130b, 130c, and 130d for dressing the processing pads (Pd1 to Pd4). The dresser 130a is a dresser for the first processing pad Pd1, the dresser 130b is a dresser for the second processing pad Pd2, the dresser 130c is a dresser for the third processing pad Pd3, and the dresser 130d is a dresser for the fourth processing pad Pd4. The processing apparatus I can dress the processing pads by bringing the processing pads into contact with the surfaces of the dressers and rotating the processing pads.

The dressers illustrated in FIG. 11 are merely one example of dressers, and the positions, sizes, and the like of the dressers in the actual processing apparatus 1 are not limited to those illustrated in FIG. 11. If the processing apparatus 1 includes both the support base 17 and the dressers, the dressers are preferably positioned so as not to overlap with the support base 17 (so as not to interfere with the support base 17).

If the plurality of heads are located above the table 10 before the attachment/removal work of the substrate Wf or the maintenance work of the substrate Wf, as illustrated in FIG. 2, the control device 100 preferably controls the plurality of swing devices such that the plurality of heads are located outside the table 10, as illustrated in FIG. 3. In this case, the arms 71a and 81a swing like “double doors”, and the arms 71b and 81b also swing like “double doors”. This ensures that when the plurality of heads are positioned outside the table 10, the arms, heads, and swing shafts do not interfere with the attachment/removal work or the maintenance work of the substrate Wf, and this makes it easy to perform the attachment/removal work or the maintenance work of the substrate Wf.

According to the present embodiment as described above, the substrate Wf can be processed by a plurality of processing pads (specifically, at least the first processing pad Pd1 and the second processing pad Pd2). This allows the substrate Wf to be processed (for example, polished) in a short time compared to the case where the substrate Wf is processed by only a single processing pad.

According to the present embodiment, the first processing pad Pd1 having a relatively large area can be used to process (specifically, polish) a wide area of the substrate Wf, and the second processing pad Pd2 having a relatively small area can be used to process a local area of the substrate Wf. As a result, the first processing pad Pd1 can maintain the processing rate (specifically, the polishing rate), while the second processing pad Pd2 can ensure the uniformity of the film thickness of the substrate Wf.

Next, a specific example of control of the control device 100 will be described. For example, the control device 100 may control the processing apparatus 1 (specifically, the swing device of the processing apparatus 1) so as to polish the entire surface to be processed Wfa of the substrate Wf with at least one processing pad (referred to as a “specific processing pad”) selected from among the plurality of processing pads. In this case, the control device 100 may also control the processing apparatus 1 so as to locally polish a portion of the surface to be processed Wfa of the substrate Wf, where the film thickness of the substrate Wf is relatively large in comparison to the rest of the substrate, with at least one processing pad selected from among the plurality of processing pads other than the specific processing pad.

Specifically, in this case, before the start of processing of the substrate Wf and/or during processing of the substrate Wf, the control device 100 acquires the overall film thickness of the substrate Wf and acquires the portion of the substrate Wf relatively large in film thickness, based on the result of detection by the film thickness sensor 111. Then, during processing of the substrate Wf, the control device 100 may polish the entire (whole) surface to be processed Wfa of the substrate Wf using the first processing pad Pd1 of the first head 30a (and/or the third processing pad Pd3 of the third head 30b), for example, while locally (or intensively) polishing the portion of the substrate Wf relatively large in film thickness in comparison to the rest of the substrate (portion larger in film thickness than other portions) using the second processing pad Pd2 of the second head 40a (and/or the fourth processing pad Pd4 of the fourth head 40b), for example.

According to this configuration, the film thickness of the substrate Wf can be made uniform in an early stage. In particular, the film thickness distribution in the circumferential direction of the substrate Wf can be made uniform in an early stage. This shortens the processing time of the entire substrate Wf.

The control device 100 may control the pressing force of at least one pressing device selected from the plurality of pressing devices based on the film thickness of the substrate Wf such that the pressing force applied by the pressing device varies depending on the film thickness of the substrate Wf. According to this configuration, the film thickness of the substrate Wf can be made uniform in an early stage.

As a specific example, as in the example described above, in the case of locally polishing a portion of the substrate Wf relatively large in film thickness in comparison to the rest of the substrate with the second processing pad Pd2 of the second head 40a, for example, the pressing force applied to the second head 40a may be changed according to the film thickness of the substrate Wf such that the pressing force applied to the second head 40a becomes stronger as the film thickness of the substrate Wf becomes larger.

In this case, for example, the storage device 102 of the control device 100 may store in advance a control map that associates the pressing force applied by the pressing device with the film thickness of the substrate Wf. This control map specifies that the pressing force becomes stronger as the film thickness of the substrate Wf becomes larger, for example. During processing, the control device 100 acquires the film thickness of the substrate Wf based on the result of detection by the film thickness sensor 111, acquires a pressing force corresponding to the acquired film thickness from the control map, and controls the pressing device so as to obtain the acquired pressing force. This makes it possible to easily change the pressing force according to the film thickness of the substrate Wf.

Alternatively, if the control device 100 acquires (detects) a portion of the substrate Wf relatively large in film thickness in comparison to the rest of the substrate based on the result of detection by the film thickness sensor 111 during processing, the control device 100 may control the pressing device (second pressing device 65a) such that the pressing force applied to the processing pad (for example, the second processing pad Pd2) configured to polish the portion of the substrate Wf relatively large in film thickness is stronger than the pressing force applied to the first processing pad Pd1. Also in this configuration, the pressing force can be easily changed according to the film thickness of the substrate Wf.

If there are a plurality of portions large in film thickness, the control device 100 may locally polish one portion selected from the plurality of portions using the second processing pad Pd2, and locally polish one portion selected from the remaining portions using the fourth processing pad Pd4. That is, the portions of the substrate Wf large in film thickness may be locally polished by sharing the work between the second processing pad Pd2 and the fourth processing pad Pd4.

The control device 100 may control the pressing force applied by at least one pressing device selected from the plurality of pressing devices, based on the rotation phase of the table 10.

Specifically, in this case, for example, the storage device 102 of the control device 100 may store in advance a control map that associates the pressing force applied by the pressing device with the rotation phase of the table 10. This control map may be configured such that the pressing force applied by the pressing device changes according to the rotation phase of the table 10, for example. During processing, the control device 100 acquires the rotation phase of the table 10 based on the result of detection by the sensor group 110 (specifically, the phase sensors), and acquires the pressing force corresponding to the acquired rotation phase from the control map. The control device 100 controls the pressing device so as to obtain the acquired pressing force. This makes it easy to control the pressing force of the pressing device based on the rotation phase of the table 10.

Film thickness distribution information of the substrate Wf may be information measured by a film thickness measuring device (not illustrated) outside the processing apparatus 1, for example. In this case, the film thickness distribution information of the substrate Wf measured by the film thickness measuring device is stored in the memory device 102 of the control device 100 of the processing apparatus 1. For example, in placing the substrate Wf on the table 10, a notch provided in the substrate Wf is always positioned at a predetermined angle on the table 10, so that polar coordinates in the film thickness distribution information of the substrate Wf and the rotation phase of the table 10 can be correlated with each other.

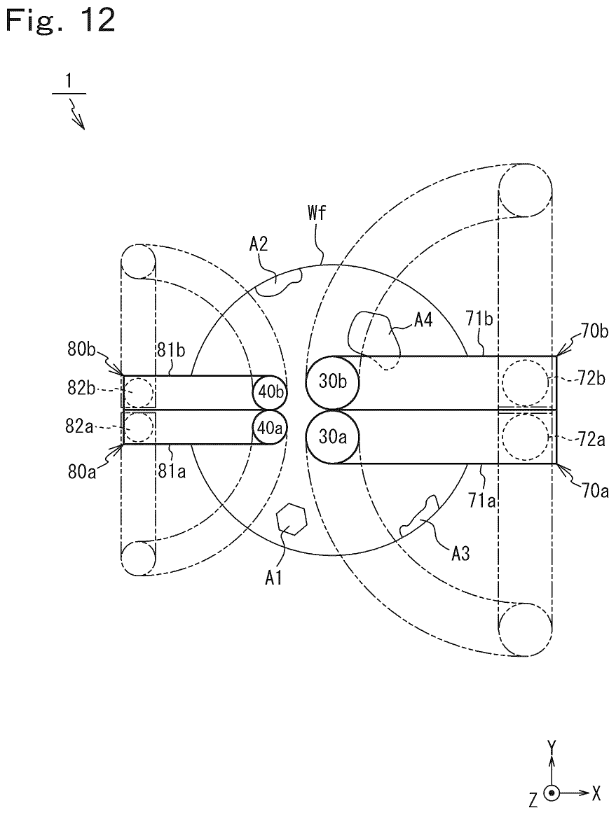

Alternatively, the control device 100 may control the processing apparatus 1 as described below. First, a schematic diagram for describing this control is provided in FIG. 12. FIG. 12 illustrates “thick film regions (A1, A2, A3, and A4)” in which the film thickness of the substrate Wf is larger than a reference value.

For example, with respect to the second head 40a, the control device 100 may increase the pressing force of the second head 40a when the thick film region A1 comes under the second head 40a. For example, with respect to the fourth head 40b, the control device 100 may increase the pressing force of the fourth head 40b when the thick film region A1 comes under the fourth head 40b. In this case, the control device 100 may swing the second head 40a or the fourth head 40b within a required angle range while the head polishes the thick film region A1. Further, if the planarization of the thick film region A1 progresses or completes, the control device 100 may move the second head 40a or the fourth head 40b to a swing position corresponding to another region (for example, the thick film region A4) to continue polishing.

With respect to the third head 30b, the control device 100 may increase the pressing force of the third head 30b when the thick film regions A2 and A3 come under the third head 30b. At this time, even if the third head 30b is larger than the thick film regions A2 and A3, the third head 30b is arranged so as to straddle the outer circumferential region of the substrate Wf and the support base 17, so that the thick film regions A2 and A3 can be preferentially polished.

The control device 100 may also control the first head 30a so as to polish uniformly from the center to the outer periphery of the substrate Wf. With respect to the first head 30a, the control device 100 may increase the pressing force of the first head 30a when the thick film region A4 comes under the first head 30a. The third head 30b may polish the outer periphery region of the substrate Wf, where the thick film regions A2 and A3 exist, and the first head 30a may perform polishing in a swing range inside the outer periphery region.

If it is not necessary to polish the entire surface of the substrate Wf from the center to the outer periphery, each head may be changed to a low pressing force so that polishing does not substantially progress, or the head may be moved away from the substrate

Wf, at a predetermined timing (for example, a timing at which the pressing force is not increased).

In this way, in order to increase the pressing force of a head when the thick film region comes under the head and perform localized polishing, it is preferable to change the pressing force responsively. A configuration for achieving this will be described later. If the substrate Wf partially has a “thin film region (a region with a film thickness lower than a reference value)”, the control device 100 may control each head to polish a region other than the thin film region.

However, the present invention is not limited to the above configuration, and the control device 100 may control the pressing force of the pressing device to be constant during processing. In this case, the control device 100 may change the rotation speed of the table 10 while keeping the pressing force of the pressing device at a constant level (a preset value).

Specifically, in this case, during processing, for example, the control device 100 brings at least one processing pad selected from the plurality of processing pads (for example, the second processing pad Pd2) into contact with a portion of the substrate Wf relatively large in film thickness, and reduces the rotation speed of the table 10 below a reference value (normal rotation speed) while keeping the pressing force of the second processing pad Pd2 at a constant level to lengthen the time during which the substrate Wf and the processing pad are in contact. Even in this case, the portion of the substrate Wf relatively large in film thickness can be polished intensively with the second processing pad Pd2. Instead of changing the rotation speed of the table 10, the rotation speed of the second processing pad Pd2 may be changed.

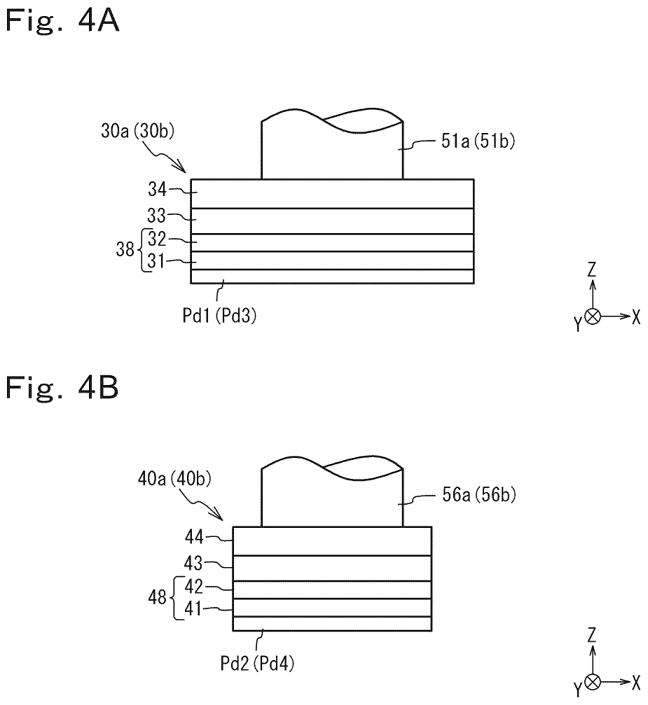

Next, peripheral configurations of the heads will be described. FIG. 4A is a schematic diagram for describing a peripheral configuration of the first head 30a, and FIG. 4B is a schematic diagram for describing a peripheral configuration of the second head 40a. The first head 30a according to the present embodiment includes, as an example, a holder plate 38 to which the first processing pad Pd1 is attached, a base plate 34 arranged above the holder plate 38, and a rubber buffer plate 33 arranged between the holder plate 38 and the base plate 34.

The holder plate 38 according to the present embodiment includes, as an example, a pad table 31 to which the first processing pad Pd1 is attached, and a pad holder 32 to which the first pad table is attached.

The second head 40a in the present embodiment includes, as an example, a holder plate 48 to which the second processing pad Pd2 is attached, a base plate 44 arranged above the holder plate 48, and a rubber buffer plate 43 arranged between the holder plate 48 and the base plate 44.

The holder plate 48 according to the present embodiment includes, as an example, a pad table 41 to which the second processing pad Pd2 is attached, and a pad holder 42 to which the pad table 41 is attached.

The first processing pad Pd1 is attached to the pad table 31 via an adhesive, as an example. The pad table 31 is attached to the pad holder 32 by a magnet or the like, as an example. The pad holder 32, the buffer plate 33, and the base plate 34 are connected to each other by fastening members such as bolts, as an example.

Similarly, the second processing pad Pd2 is attached to the pad table 41 by an adhesive or the like, as an example. The pad table 41 is attached to the pad holder 42 by a magnet or the like, as an example. The pad holder 42, the buffer plate 43, and the base plate 44 are connected to each other by fastening members such as bolts, as an example.

The third head 30b according to the present embodiment has a configuration similar to that of the first head 30a described above. That is, the third head 30b also includes a holder plate 38 (which holds the third processing pad Pd3), a base plate 34, and a rubber buffer plate 33. The fourth head 40b according to the present embodiment has a configuration similar to that of the second head 40a described above. That is, the fourth head 40b also includes a holder plate 48 (which holds the fourth processing pad Pd4), a base plate 44, and a rubber buffer plate 43.

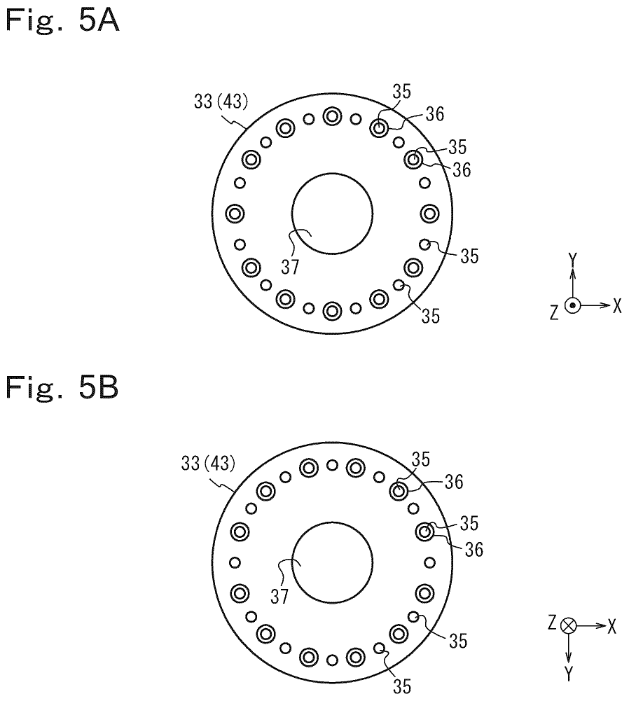

FIG. 5A is a schematic top view of the buffer plate 33, and FIG. 5B is a schematic bottom view of the buffer plate 33. As described above, in the case of attaching the buffer plate 33 using bolts, the buffer plate 33 may be provided with through holes 35 through which the bolts for connecting the base plate 34 and the buffer plate 33 and the bolts for connecting the pad holder 32 and the buffer plate 33 are inserted. The buffer plate 33 may also be provided with countersinks 36 in which the heads of the bolts are arranged. According to this configuration, it is possible to prevent the heads of the bolts from protruding outward from the buffer plate 33.

The buffer plate 33 may have a ring shape with a through hole 37 in the center thereof. However, the present invention is not limited to this configuration, and the buffer plate 33 may have a disk shape without the through hole 37.

The buffer plate 43 may have the same configuration as the buffer plate 33 described above. That is, the buffer plate 43 may also be provided with through holes 35 for inserting bolts and countersinks 36 for arranging the heads of the bolts. The buffer plate 43 may also have a ring shape with a through hole 37 in the center thereof. Alternatively, the buffer plate 43 may have a disk shape without the through hole 37.

According to the present embodiment, since the first head 30a and the third head 30b include the rubber buffer plate 33, even if the head rotation axis is not strictly perpendicular to the table 10, the buffer plate 33 absorbs the inclination of the rotation axis, so that the entire bottom surfaces of the processing pads can be easily brought into contact with the substrate Wf. In addition, even if the surface of the substrate Wf periodically moves up and down due to the surface accuracy of the table 10, the buffer plate 33 can absorb the undulations of the surface of the substrate Wf. Further, according to this configuration, it is possible to quickly transmit the pressing force applied from the first pressing device 60a and the third pressing device 60b to the first processing pad Pd1 and the third processing pad Pd3, compared to a case where the first head 30a and the third head 30b are provided with an “buffer member of an airbag (airbag-type buffer member)” instead of the buffer plate 33, for example.

Similarly, according to the present embodiment, the second head 40a and the fourth head 40b are provided with the rubber buffer plate 43, so that the entire bottom surfaces of the processing pads can be easily brought into contact with the substrate Wf. Further, according to this configuration, it is possible to quickly transmit the pressing force applied by the second pressing device 65a and the fourth pressing device 65b to the second processing pad Pd2 and the fourth processing pad Pd4, compared to a case where the second head 40a and the fourth head 40b are provided with an airbag-type buffer member instead of the buffer plate 43, for example.

Next, a peripheral configuration of the table 10 will be described. FIG. 6A is a schematic top view of the table 10. FIG. 6B is a schematic cross-sectional view of the table 10. In FIG. 6B, the outer diameter of the table 10 and the outer diameter of the substrate Wf are the same. In the case of holding the substrate Wf on the table 10 by a vacuum chuck method, the table 10 is provided with a suction port 14 for sucking air as illustrated in FIGS. 6A and 6B. Specifically, the suction port 14 may be provided in the center of the top surface 10a of the table 10, for example. Also, referring to FIG. 6B, the bottom surface of the table 10 is provided with an exhaust port 15 for discharging the sucked air. The exhaust port 15 is connected to a suction device (not illustrated) such as a vacuum pump by piping (not illustrated). Also, the table 10 has therein a gas passage 16 that communicates between the suction port 14 and the exhaust port 15.

The number of suction port 14 is not limited to one, and a plurality of suction ports 14 may be provided on the top surface 10a of the table 10, for example. The shape of the suction port 14 is not particularly limited, and various shapes can be used, such as a circular shape, an annular shape, a shape in which a plurality of straight lines intersect (for example, a cross shape), a polygonal shape, or a shape consisting of a combination of two or more shapes selected from these shapes.

After the substrate Wf is placed on the top surface 10a of the table 10, air is sucked through the suction port 14, whereby the substrate Wf can be held on the top surface 10a of the table 10 by the vacuum chuck method.

In the case of holding the substrate Wf on the table 10 by the vacuum chuck method, the substrate Wf may be held using a “pin chuck method” in order to distribute the suction pressure applied to the substrate Wf while maintaining the force of holding the substrate Wf. Specifically, in this case, a plurality of pins are arranged on the top surface 10a of the table 10 so as to protrude upward. The substrate Wf is placed on the tips (upper ends) of the plurality of pins. With the substrate Wf placed on the plurality of pins, air is sucked in through the suction port 14, so that the substrate Wf can be held on the table 10.

Referring to FIGS. 6A and 6B, a plurality of discharge ports 11 configured to discharge a liquid (water as an example in the present embodiment) upward may be provided in an outer edge region RM of the top surface 10a of the table 10. Specifically, the discharge ports 11 are configured to discharge a liquid toward the bottom surface of the substrate Wf arranged on the top surface 10a of the table 10 (that is, the bottom surface of the substrate Wf facing the top surface 10a of the table 10). In the present embodiment, the plurality of discharge ports 11 are arranged at equal intervals in the circumferential direction of the table 10, as an example.

The outer edge region RM of the top surface 10a refers to a region extending from the outer edge (the outermost end) of the top surface 10a to the center of the top surface 10a by a predetermined distance (the outer edge region RM also includes the outer edge of the top surface 10a). The specific value of the predetermined distance is not particularly limited, but a value of 1/10 or less of the diameter of the top surface 10a can be used, for example.

As illustrated in FIG. 6B, provided on the bottom surface of the table 10 is a supply port 12 through which a liquid (water) is supplied, for example. The supply port 12 is connected to a pressure-feeding device (not illustrated) such as a liquid pump by piping (not illustrated). In addition, provided inside the table 10 is a liquid passage 13 that communicates between the supply port 12 and the plurality of discharge ports 11. The liquid (water) supplied to the supply port 12 passes through the liquid passage 13 and is discharged from the plurality of discharge ports 11. The plurality of discharge ports 11 may continue to discharge the liquid from the start to the end of the processing of the substrate Wf, for example.

According to this configuration, it is possible to suppress intrusion of foreign matter (including polishing slurry, for example) between the substrate Wf and the table 10 by using the liquid discharged from the plurality of discharge ports 11. Specifically, it is possible to remove the slurry that flows around the edge of the substrate Wf to the outside of the substrate Wf by using the liquid (water) discharged upward from the plurality of discharge ports 11. This restrains foreign matter such as slurry from entering the inner area beyond the discharge ports 11 and being sucked into the suction port 14. That is, the liquid discharged upward from the plurality of discharge ports 11 functions as a “water seal (or a “liquid wall”)”. This suppresses intrusion of foreign matter between the substrate Wf and the table 10.

The discharge ports 11 are provided radially inside the outer edge of the substrate Wf placed on the table 10. In the case of providing the discharge ports 11 inside the outer edge of the substrate Wf, the positions (height positions) of the discharge ports 11 on the top surface of the table 10 may be located lower than other places on the top surface of the table 10, for example, in order to prevent the substrate Wf from completely blocking the discharge ports 11 and suppressing the discharge of the liquid from the discharge ports 11. As described above, in the case of holding the substrate Wf by the “pin chuck method”, the discharge ports 11 may be provided at positions lower than the upper ends of the plurality of pins.

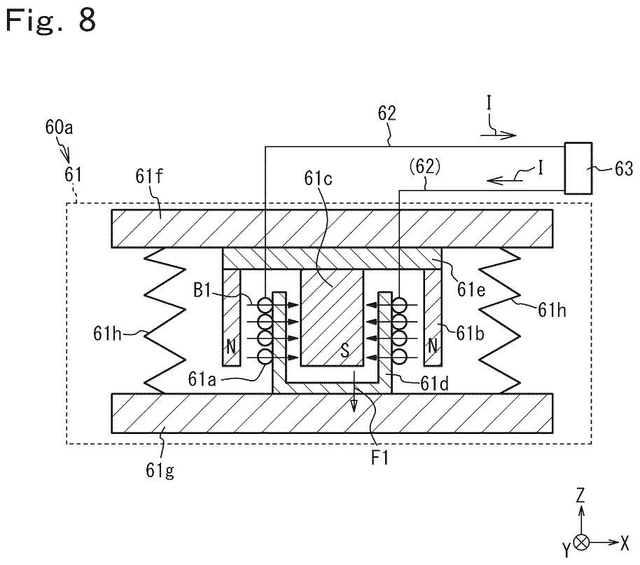

Next, a peripheral configuration of the pressing device will be described. FIGS. 7 and 8 are schematic cross-sectional views for describing details of the first pressing device 60a. Specifically, FIG. 7 illustrates an example of a peripheral configuration of the first pressing device 60a. FIG. 8 is an enlarged cross-sectional view of the first pressing device 60a in FIG. 7. Referring to FIGS. 7 and 8, the first pressing device 60a includes an electromagnetic actuator 61 that is configured to apply a pressing force to the first head 30a by using an electromagnetic force. In the present embodiment, a “voice coil motor” is used as a specific example of the electromagnetic actuator 61.

Referring to FIG. 8, specifically, the electromagnetic actuator 61 (voice coil motor) according to the present embodiment includes a coil 61a and magnets (magnets 61b and 61c) configured to generate an electromagnetic force (F1), and is configured to apply the generated electromagnetic force (F1) to the first head 30a as the above-described pressing force.

More specifically, the electromagnetic actuator 61 according to the present embodiment includes, in addition to the coil 61a and the magnets described above, a coil core 61d, a support plate 61e, an upper plate 61f, a lower plate 61g, and a spring 61h.

The coil 61a is wound around the cylindrical coil core 61d (in the present embodiment, the cylindrical bottomed coil core, as an example). The lower end (the bottom in the present embodiment) of the coil core 61d is connected to the top surface of the lower plate 61g. The coil 61a is electrically connected to a power source 63 as a current supply device via wiring 62. The power source 63 supplies a current (I) to the coil 61a in response to an instruction from the control device 100, for example.

The magnet includes a pair of magnets, specifically, the magnet 61b (N pole) and the magnet 61c (S pole).

The upper ends of the magnets 61b and 61c are connected to the support plate 61e. The support plate 61e is connected to the bottom surface of the upper plate 61f. That is, the magnets 61b and 61c according to the present embodiment are connected to the upper plate 61f via the support plate 61e. The first pressing device 60a may be configured not to include the support plate 61e. In this case, the magnets 61b and 61c are directly connected to the upper plate 61f.

The magnet 61b according to the present embodiment is formed in a cylindrical shape, for example, and arranged outside (outer periphery side) of the coil 61a with a space left from the coil 61a. Alternatively, the magnet 61b may be a bar-shaped magnet extending in the vertical direction. In this case, for example, the electromagnetic actuator 61 may include a plurality of magnets 61b, and the plurality of magnets 61b may be arranged outside the coil 61a with a space left from the coil 61a.

The magnet 61c according to the present embodiment has a columnar shape, for example. The magnet 61c is arranged inside the coil 61a, specifically, inside the coil core 61d around which the coil 61a is wound. A magnetic field (B1) is formed between the magnets 61b and 61c, which is directed from the magnet 61b to the magnet 61c. The coil 61a is arranged inside the magnetic field (B1).

The upper plate 61f and the lower plate 61g are connected to each other via springs 61h. This allows the distance (vertical distance) between the upper plate 61f and the lower plate 61g to change. The springs 61h according to the present embodiment are arranged on the outer side (outer periphery side) of the magnet 61b.

Referring to FIG. 7, the lower plate 61g according to the present embodiment is connected via a load cell 112 to the first head rotation device 50a (specifically, the housing portion of the first head rotation device 50a).

Referring to FIG. 8, when the current (I) is supplied to the coil 61a of the electromagnetic actuator 61, the coil core 61d receives a downward electromagnetic force (F1) according to Fleming's left-hand rule. As a result, the lower plate 61g connected to the coil core 61d also receives the downward force (F1). The force (F1) received by the lower plate 61g is transmitted to the first head 30a via the head rotation shaft 51a, thereby applying a pressing force to the first head 30a.

With the above-described mechanism, the first pressing device 60a according to the present embodiment applies a pressing force to the first head 30a. The second pressing device 65a, the third pressing device 60b, and the fourth pressing device 65b according to the present embodiment have the same configuration as that of the first pressing device 60a. That is, the second pressing device 65a, the third pressing device 60b, and the fourth pressing device 65b according to the present embodiment also include an electromagnetic actuator 61, and are configured to apply a pressing force to the head by using the electromagnetic force generated by the electromagnetic actuator 61.

Instead of the electromagnetic actuator 61, a known pressing mechanism such as an air cylinder or a ball screw may be used as the pressing device. However, in the case of using an air cylinder, for example, it may take a certain amount of time to generate a predetermined pressing force because it is necessary to increase the internal pressure of the air cylinder by controlling a pressure control device such as a regulator. In the case of using a ball screw, it may take a certain amount of time until a predetermined pressing force is generated because the ball screw needs to rotate a certain number of times to generate the predetermined pressing force. Therefore, it is difficult for pressing mechanisms such as an air cylinder or a ball screw to quickly apply a pressing force.

In contrast, according to the present embodiment, since the pressing device includes the electromagnetic actuator 61, it is possible to apply a pressing force to the head more quickly, compared to a case in which the pressing device includes a pressing mechanism such as an air cylinder or a ball screw instead of the electromagnetic actuator 61. That is, according to the present embodiment, it is possible to improve the responsiveness of the application of a pressing force.

Specifically, according to the present embodiment, it is possible to quickly apply a pressing force to the head by passing a current through the coil 61a of the electromagnetic actuator 61. In addition, it is possible to quickly change the pressing force applied to the head by changing the value of the current flowing through the coil 61a. Specifically, the pressing force applied to the head can be quickly increased by increasing the value of the current flowing through the coil 61a, and the pressing force applied to the head can be quickly decreased by decreasing the value of the current flowing through the coil 61a.

Consequently, according to the present embodiment, a high pressing force can be applied quickly to a portion of the substrate Wf which is large in film thickness, for example. As a result, the substrate Wf can be processed in a short time.

Next, modifications of the above-described embodiment will be described below.

### Modification 1

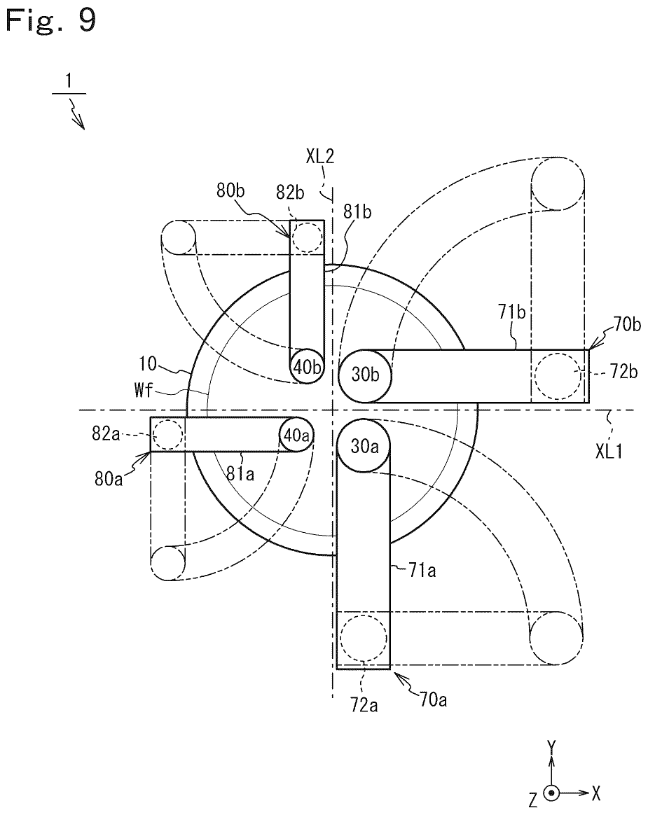

FIG. 9 is a schematic diagram for describing a processing apparatus 1 according to Modification 1 of the embodiment. Specifically, FIG. 9 schematically illustrates swinging of a plurality of heads in a processing apparatus 1 according to this modification, as in FIG. 2 described above.

The processing apparatus 1 according to this modification illustrated in FIG. 9 differs from the embodiment illustrated in FIG. 2 in that a swing shaft 72a of a first swing device 70a is arranged near a second center axis line XL2, and a swing shaft 82b of a fourth swing device 80b is arranged near the second center axis line XL2. The other configurations of the processing apparatus 1 according to this modification are the same as those of the processing apparatus 1 according to the above-described embodiment. In this modification, the operational advantage similar to the above-described embodiment can be provided as well.

### Modification 2

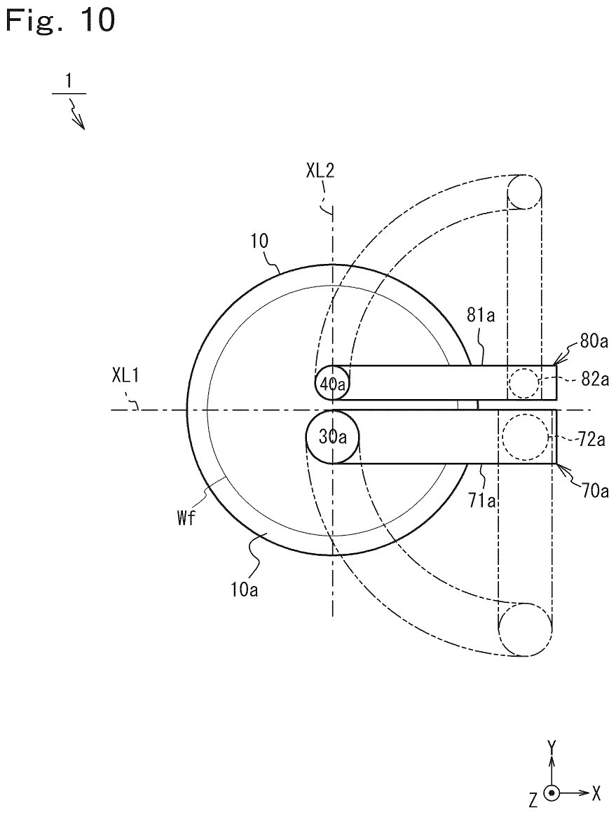

FIG. 10 is a schematic diagram for describing a processing apparatus 1 according to Modification 2 of the embodiment. Specifically, FIG. 10 schematically illustrates swinging of a plurality of heads in a processing apparatus 1 according to this modification, as in FIG. 2 described above.

The processing apparatus 1 according to this modification illustrated in FIG. 10 does not include a third head 30b, a fourth head 40b, and a swing device that swings them. In addition, in the processing apparatus 1 according to this modification, a swing shaft 82a of a second swing device 80a is arranged in one of two regions defined by a second center axis line XL2 (the region on the X-direction side of the second center axis line XL2), and is arranged in the other of two regions defined by a first center axis line XL1 (the region on the Y-direction side of the first center axis line XL1). In the above points, this modification is different from the embodiment illustrated in FIG. 2. The other configurations of the processing apparatus 1 according to this modification are the same as those of the processing apparatus 1 according to the above-described embodiment. In this modification, the operational advantage similar to the above-described embodiment can be provided as well.

Although the embodiment and modifications according to the present invention have been described in detail above, the present invention is not limited to such specific embodiment or modifications, and various kinds of modifications and changes are possible within the scope of the present invention described in the claims.

### REFERENCE SIGNS LIST

1 . . . processing apparatus
10 . . . table
10a . . . top surface
11 . . . discharge port
20 . . . table rotation device
30a . . . first head
33 . . . buffer plate
34 . . . base plate
38 . . . holder plate
40a . . . second head
43 . . . buffer plate
44 . . . base plate
48 . . . holder plate
61 . . . electromagnetic actuator
70a . . . first swing device
72a . . . swing shaft
80a . . . second swing device
82a . . . swing shaft
100 . . . control device
Pd1 . . . first processing pad
Pd2 . . . second processing pad
RM . . . outer edge region
Wf . . . substrate
Wfa . . . surface to be processed
XL1 . . . first center axis line
XL2 . . . second center axis line

What is claimed is:

1. A processing apparatus configured to perform a polishing process as a predetermined process on a substrate, comprising:
a table configured to hold the substrate such that a surface to be processed of the substrate faces upward;
a table rotation device configured to rotate the table;
a plurality of heads to each of which a processing pad is attached, the processing pad having an area smaller than an area of the surface to be processed of the substrate, the plurality of heads being configured to bring the processing pad into contact with the surface to be processed of the substrate;
a plurality of head rotation devices each configured to rotate a corresponding one of the plurality of heads;
a plurality of pressing devices each including an electromagnetic actuator configured to apply a pressing force to a corresponding one of the plurality of heads by utilizing electromagnetic force; and
a plurality of swing devices each configured to swing a corresponding one of the plurality of heads.

2. The processing apparatus according to claim 1, wherein
each of the plurality of heads includes a holder plate to which the processing pad is attached, a base plate arranged above the holder plate, and a rubber buffer plate arranged between the holder plate and the base plate.

3. The processing apparatus according to claim 1, wherein
an outer edge region is a region extending a predetermined distance from an outer edge of a top surface of the table toward a center of the top surface, and the outer edge region is provided with a plurality of discharge ports configured to discharge liquid toward a bottom surface of the substrate placed on the top surface.

4. The processing apparatus according to claim 1, wherein
the plurality of heads include a first head to which a first processing pad is attached and a second head to which a second processing pad is attached,
the plurality of swing devices include a first swing device configured to swing the first head and a second swing device configured to swing the second head,
the first swing device includes a first swing shaft and is configured to swing the first head around the first swing shaft,
the second swing device includes a second swing shaft and is configured to swing the second head around the second swing shaft, and
the first swing shaft and the second swing shaft are arranged in a region outer than the table in a top view.

5. The processing apparatus according to claim 4, wherein
assuming a first center axis line that passes through a center of the table in the top view and a second center axis line that passes through the center and is perpendicular to the first center axis line,
the first swing shaft and the second swing shaft are arranged in one of two regions defined by the first center axis line, and
the first swing shaft is arranged in one of two regions defined by the second center axis line, and the second swing shaft is arranged in the other of the two regions defined by the second center axis line.
